(19) United States
(12) Patent Application Publication
(10) Pub. No.: US 2025/0261331 A1
(43) Pub. Date: Aug. 14, 2025

(54) EMERGENCY COOLING SYSTEM

(71) Applicant: VERTIV CORPORATION, Westerville, OH (US)

(72) Inventors: Jerome A. Maloney, Sugar Grove, IL (US); Peter M. Sprague, Big Rock, IL (US); Jin H. Elkins, Auburn, AL (US); Matthew A. Podemski, Auburn, AL (US)

(21) Appl. No.: 19/037,959

(22) Filed: Jan. 27, 2025

Related U.S. Application Data
(60) Provisional application No. 63/553,324, filed on Feb. 14, 2024.

(51) Int. Cl. H05K 7/20

(52) U.S. Cl. CPC H05K 7/20181; H05K 7/20145; H05K 7/20209; H05K 7/20736; H05K 7/20827

(57) ABSTRACT

An emergency cooling system for a cabinet may include an exhaust assembly frame comprising one or more exhaust apertures. The emergency cooling system for the cabinet may include one or more flaps configured to reversibly engage the one or more exhaust apertures. The one or more flaps may be coupled via a hinge to the frame. The weight of the one or more flaps may biases the one or more flaps toward a closed position.

### CROSS-REFERENCE TO RELATED APPLICATIONS

The present application claims priority to U.S. Provisional Patent Application No. 63/553,324, filed Feb. 14, 2024, which is incorporated herein by reference in its entirety.

### TECHNICAL FIELD

The present disclosure relates to cooling systems for cabinets, and more particularly for emergency cooling systems for power/equipment cabinets.

### BACKGROUND

Telecommunication and computing industries rely on cooling systems to keep temperature-sensitive equipment (e.g., servers, computers) operating under rated or normal environmental conditions. For vital systems, independently operating backup cooling systems, such as backup cooling systems for power/equipment cabinets (e.g., server cabinets), are also employed so that proper cooling can be maintained when the main cooling systems have failed. However, backup cooling systems can be difficult to employ, particularly if the backup cooling system is to be added to a legacy system (e.g., retrofitting). Backup cooling systems can also be expensive, requiring complex components. Accordingly, it may be advantageous to have a backup cooling system for power/equipment cabinets that are easy to employ and/or retrofit.

### SUMMARY

Accordingly, the present disclosure is directed to an emergency cooling system for a cabinet. The emergency cooling system may include an exhaust assembly. The exhaust assembly may include an exhaust assembly frame that includes one or more exhaust apertures. The exhaust assembly may further include one or more flaps configured to reversibly engage the one or more exhaust apertures. The exhaust assembly is configured so that at least one of airflow or air pressure within the cabinet biases the one or more flaps into an open position. When the one or more flaps are in a closed position, the one or more exhaust apertures or the one or more flaps may be positioned at an angle relative to normal, such as an angle within a range of 2° to 15°.

In one or more embodiments, the emergency cooling system may further include an environmental control unit. The environment control unit may include one or more cooling fans, a temperature sensor, and at least one processor. The at least one processor may be communicatively coupled to the one or more cooling fans, the temperature sensor, and a primary cooling system. The processor may be configured to determine an operating status of the primary cooling system, receive temperature sensor data, and activate the one or more fans based on at least one of the operating status of the primary cooling system of the temperature sensor data, wherein turning on the one or more fans results in the airflow or the air pressure within the cabinet that biases the one or more flaps into the open position.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

In embodiments, an emergency cooling system for a cabinet is disclosed. In embodiments, the emergency cooling system includes an environmental control unit, the environmental control unit including: one or more cooling fans; a temperature sensor; at least one processor communicatively coupled to the one or more cooling fans, the temperature sensor, and a primary cooling system, wherein the at least one processor is configured to: determine an operating status of the primary cooling system; receive temperature sensor data; and activate the one or more fans based on at least one of the operating status of the primary cooling system of the temperature sensor data; and an exhaust assembly including: an exhaust assembly frame including one or more exhaust apertures; and one or more flaps configured to reversibly engage the one or more exhaust apertures.

In embodiments, a method for retrofitting a cabinet with an emergency cooling system is disclosed. In embodiments, the method, includes: replacing a panel of a cabinet with an exhaust panel assembly; removing a primary cooling system from a door of the cabinet and replacing the door with a new door that includes intake component of an emergency cooling system; reassembling the primary cooling system to the new door; and mounting an environmental control unit and connecting any cables from the environmental control unit to one or more fans, alarm systems, or power systems of the cabinet.

### BRIEF DESCRIPTION OF DRAWINGS

The numerous advantages of the disclosure may be better understood by those skilled in the art by reference to the accompanying figures.

FIG. 1 illustrates a perspective view of a cabinet that includes an emergency cooling system (ECS), in accordance with one or more embodiments of the disclosure.

FIG. 2 illustrates a perspective view of the cabinet of FIG. 1 with a panel opened, in accordance with one or more embodiments of the disclosure.

FIG. 3 illustrates a reverse perspective view of the cabinet of FIG. 1, in accordance with one or more embodiments of the disclosure.

FIG. 4 illustrates a perspective view of an exhaust assembly for the ECS, in accordance with one or more embodiments of the disclosure.

FIG. 5A illustrates a perspective view of an exhaust assembly for the ECS that includes an exhaust panel, in accordance with one or more embodiments of the disclosure.

FIG. 5B illustrates a side view of the cabinet and exhaust assembly, with flaps configured in a closed position, in accordance with one or more embodiments of the disclosure.

FIG. 5C illustrates a side view of the cabinet and exhaust assembly, with flaps configured in an open position, in accordance with one or more embodiments of the disclosure.

FIG. 6 illustrates a partially exploded view of a cabinet panel and the intake components of an emergency cooling system, in accordance with one or more embodiments of the disclosure.

FIG. 7 illustrates a cabinet that is to be retrofitted with an emergency cooling system, in accordance with one or more embodiments of the disclosure.

FIG. 8 illustrates a process flow diagram depicting a method for retrofitting a cabinet with an emergency cooling system, in accordance with one or more embodiments of the disclosure.

FIG. 9 illustrates a block diagram depicting a schematic of the power and data connectivity of the emergency cooling system and a primary cooling system of a cabinet, in accordance with one or more embodiments of the disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present), and B is false (or not present), A is false (or not present) and B is true (or present), and both A and B are true (or present).

In addition, the use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “embodiments” means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Disclosed is an emergency cooling system (ECS) for power/equipment cabinets, such as server cabinets. The ECS operates independently from any external or internal primary cabinet cooling system. The ECS includes componentry for producing airflow (e.g., fan) and a passive system for operating an exhaust system (e.g., an exhaust assembly) that “opens up” upon the presence of airflow or increased air pressure within the cabinet. In some embodiments, the ECS includes only the exhaust assembly. In some embodiments, the exhaust assembly is configured to be installed or retrofitted within a legacy/prebuilt cabinet.

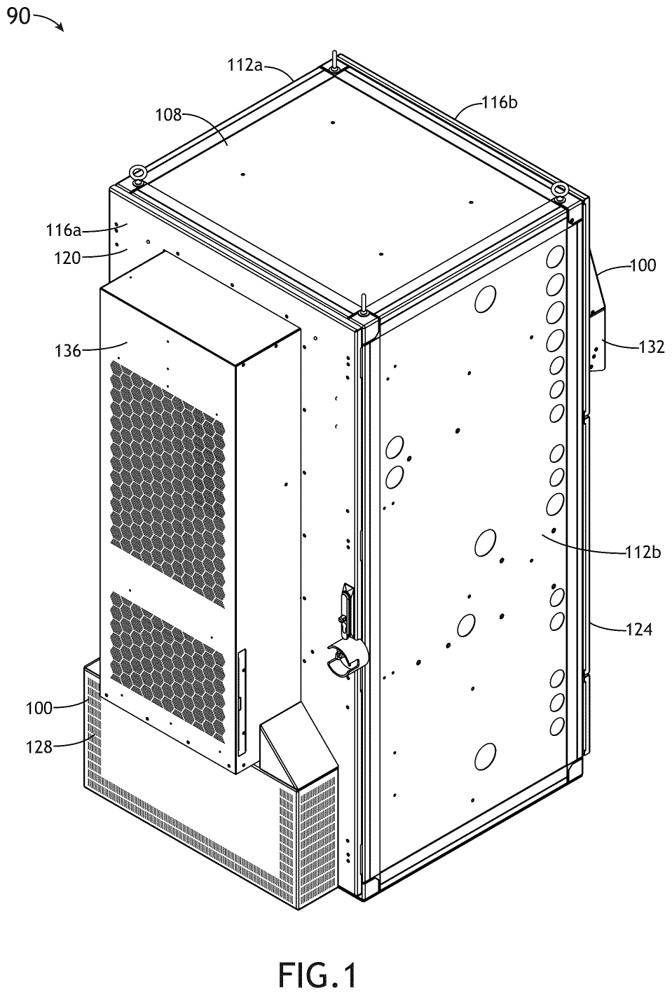

In embodiments, as illustrated in FIG. 1, a cabinet 90 that includes an ECS 100 is presented. The cabinet 90 may be any type of cabinet for storing powered equipment, telecommunication equipment, or computer equipment. For example, the cabinet 90 may be configured as a server cabinet that stores computer hardware. The cabinet 900 may include a top panel 108 one or more side panels 112a-b, and one or more doors 116a-b. The cabinet 90 may include an intake side 120 (e.g., at door 116a) and an exhaust side 124 (e.g., at door 116b). The ECS 100 may include intake components 128 (e.g., integrated into the intake side 120) and exhaust components 132 (e.g., integrated into the exhaust side 124). The cabinet 90 may also include a primary cooling system 136.

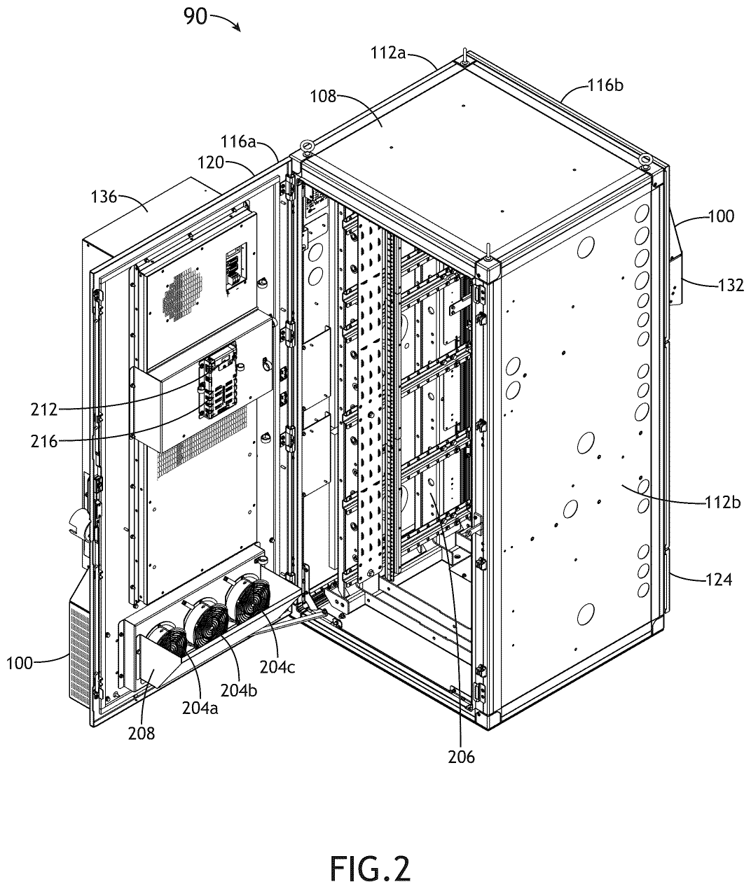

The ECS 100 may include one or more fans 204a-c, as shown in FIG. 2. When turned on, the one or more fans 204a-c cause airflow within the cabinet 90, bringing in outside air from the intake side 120, and moving the air toward the exhaust side 124 (e.g., through a storage space 206 of the cabinet 90). The movement of air by the one or more fans 204a-c may also cause an increase in air pressure within the cabinet 90 (e.g., as compared to the air pressure outside of the cabinet 90). Movement of air through the cabinet 90 may be guided via one or more fan ducts 208. The ECS 100 may further include an environmental control unit 212 that includes one or more processors that control one or more aspects of the ECS 100. The ECS 100 may further include one or more temperature sensors 216 that can sense a temperature within the cabinet 90.

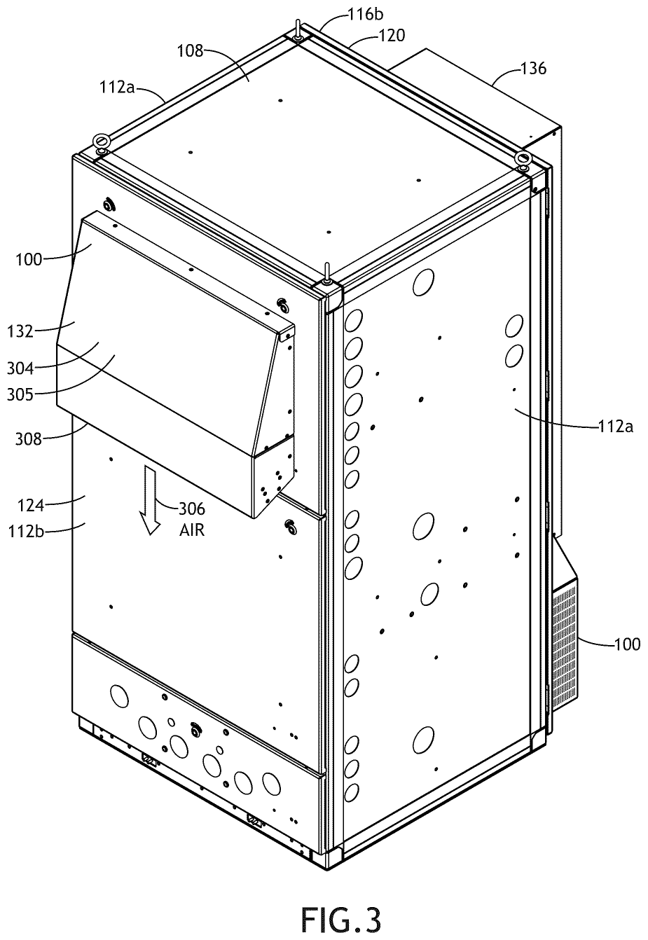

Details of the exhaust components 132 are illustrated in FIGS. 3-5. The exhaust components 132 of the ECS 100 include an exhaust assembly 304 (e.g., an external panel 305 of the exhaust assembly 304 visible in FIG. 3. When the one or more fans 204a-c of the ECS 100 are activated, air 306 is moved from inside the cabinet 90 to outside the cabinet 90 through the exhaust assembly 304 via an exhaust opening 308.

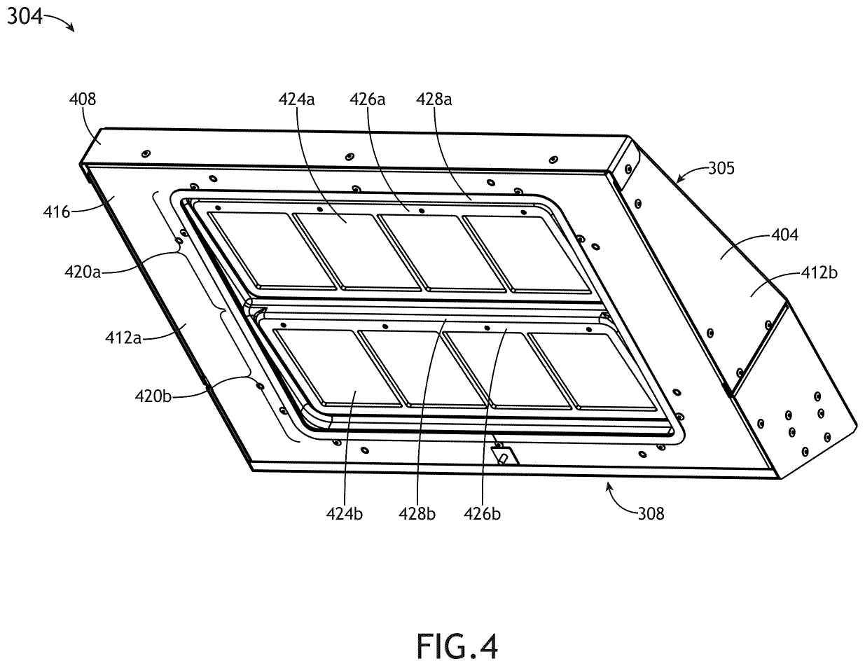

The exhaust assembly 304 includes a housing 404 that comprises the external panel 305, a top housing panel 408, side housing panels 412a-b, and a frame 416. The frame includes one or more exhaust apertures 420a-b that are engaged (e.g., can be closed off by) one or more flaps 424a-b. The one or more flaps 424a-b function to reversibly engage the exhaust apertures 420a-b similar to a duct louver or louver blade. When the one or more flaps 424a-b engage the exhaust apertures 420a-b, the exhaust assembly 304 is in a closed position, with air inhibited from entering into the housing 404 from the storage space 206 of the cabinet 90. The exhaust assembly 304 in the closed position is illustrated in FIG. 4. When the exhaust assembly 304 is in the open position, the one or more flaps 424a-b disengage at least partially from the exhaust apertures 420a-b allowing air 306 from the storage space 206 of the cabinet 90 to enter the housing 404 and exit through the exhaust opening 308. The one or more flaps 424a-b may be operatively coupled to the frame 416 or frame elements via any connectors that allow the one or more flaps 424a-b to reversibly engage the exhaust apertures 420a-b including but not limited to a hinge 426a-b, such as a hinge 426a-b that couples to a top side 428a-b of the one or more flaps 424a-b. The exhaust assembly 304 may include any number of flaps 424. For example, the exhaust assembly 304 may include a single flap 424. In another example, the exhaust assembly 304 may include two flaps 424. In another example, the exhaust assembly 304 may include three flaps 424. In another example, the exhaust assembly 304 may include four flaps 424.

In embodiments, when exhaust assembly 304 is configured in a closed position (e.g., the one or more flaps 424a-b stopping or inhibiting airflow through the exhaust apertures 420a-b), airflow and/or increases in air pressure produced by the one or more fans 204a-c may then cause the exhaust assembly 304 to change configuration to an open position, with the one or more flaps 424a-b allowing air to pass through the exhaust apertures 420a-b and out the exhaust opening 308. The difference in air pressure (e.g., between the storage space 206 and the air outside the cabinet) required to move the one or more flaps 424a-b away from the exhaust apertures 420a-b may be less than 7 kPa (e.g., less than 1 psi), may be in a range between 7 kPa and 14 kPa, may be in a range between 14 kPa and 28 kPa, may be in a range between 28 kPa and 56 kPa, or may be in a range between 56 kPa and 112 kPa. The exhaust assembly 304 is configured as a passive system, with no elements besides airflow or differences in air pressure providing the force to move the one or more flaps from a closed position to an open position. The design of the passive exhaust assembly 304 provides advantages over a comparable mechanical exhaust system in terms of cost, complexity, and reliability.

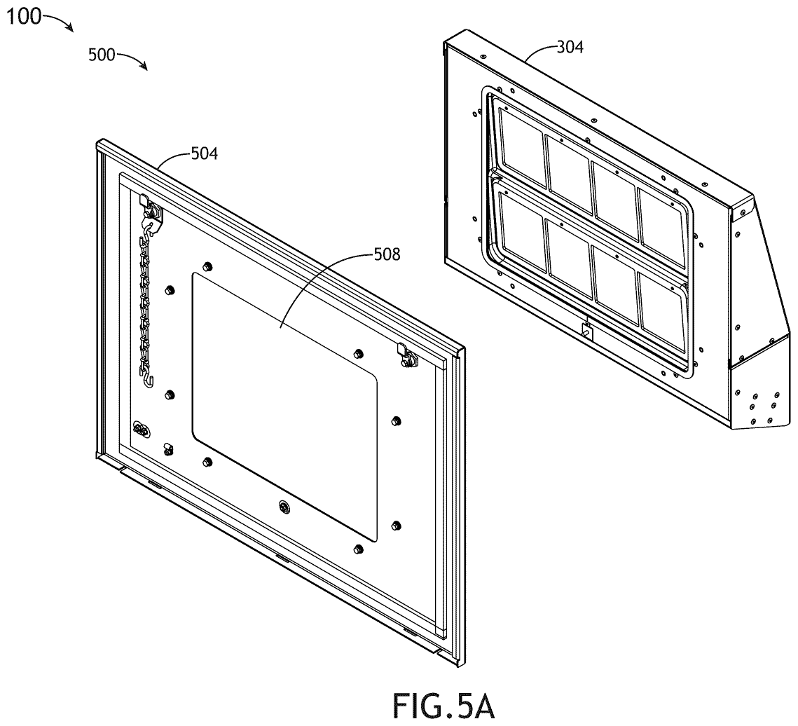

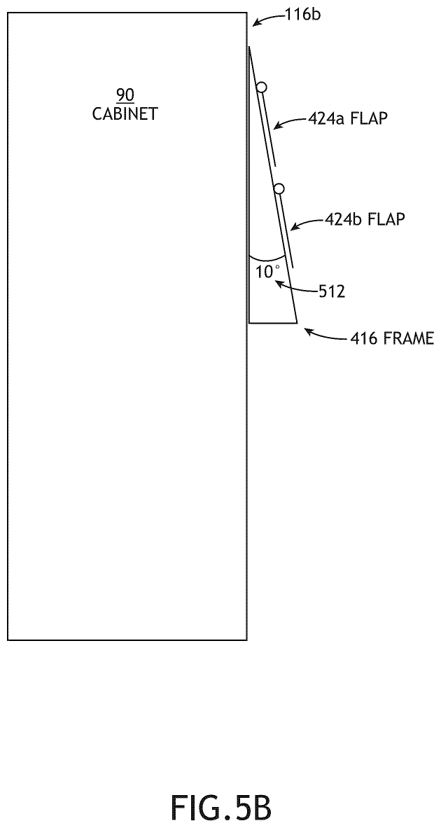

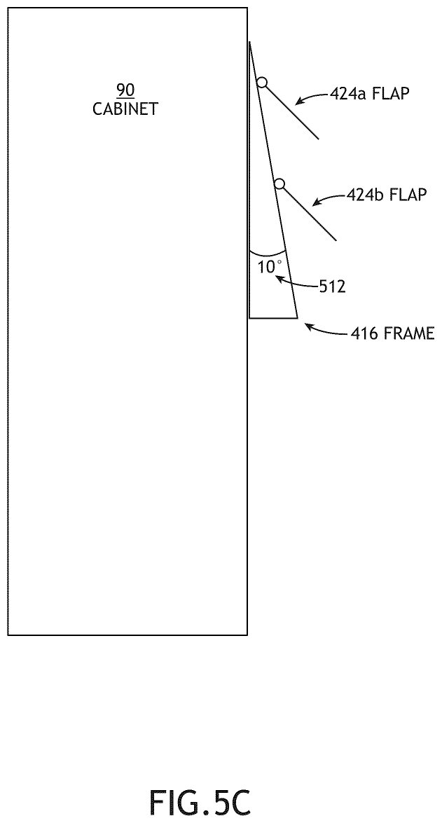

In embodiments, the exhaust assembly 304 is attached to the cabinet 90 via an exhaust panel assembly 500 that includes an exhaust panel 504, as shown in FIG. 5A. The exhaust panel 504 includes a window 508 that permits air 306 to enter into the exhaust assembly 304.

In embodiments the one or more flaps 424a-b are biased into the closed position via a weight of the one or more flaps 424a-b, as shown in FIGS. 5B and 5C. For example, the weight of the one or more flaps 424a-b may provide enough force (e.g., the one or more flaps 424a-b aided by gravity) to keep the exhaust assembly 304 in the closed position when the one or more fans 204a-c are turned off, as shown in FIG. 5B. In another example, the weight of one or more flaps 424a-b may provide enough force to keep the exhaust assembly 304 in the closed position when one or more fans 204a-c are turned off, and the primary cooling system 136 is operational. Once the one or more fans 204a-c are turned on, the airflow and/or increased air pressure opens the one for more flaps 424a-c to an open position, as shown in FIG. 5C.

In embodiments, the one or more exhaust apertures 420a-b and/or the one or more flaps 424a-b (e.g., in the closed position) are positioned at an angle 512 relative to normal (e.g., such as relative to the surface of the door 116b or side panel 112a-b of the cabinet 90). By placing the one or more exhaust apertures 420a-b and/or the one or more flaps 424a-b at the angle 512 relative to normal, the weight of the one or more flaps 424a-b biases against the one or more exhaust apertures 420a-b, positioning the one or more flaps 424a-b in the closed position when the one or more fans are turned off. The greater the angle 512, the greater the effect of the weight of the one or more flaps 4241-b upon the one or more exhaust apertures 420a-b.

In embodiments, the angle 512 of the one or more exhaust apertures 420a-b and or the one or more flaps 424a-b in the closed position relative to normal may include a range of 1° to 20°, a range of 2° to 15°, a range of 3° to 10°, a range of 4° to 10°, a range of 4° to 10°, or a range of 4° to 8°. For example, the angle 512 of the one or more exhaust apertures 420a-b and or the one or more flaps 424a-b in the closed position relative to normal may include a range from 5° to 10°. In embodiments, the angle 512 of the one or more exhaust apertures 420a-b and or the one or more flaps 424a-b in the closed position relative to normal may be approximately or substantially 3°, may be approximately or substantially 4°, may be approximately or substantially 5°, may be approximately or substantially 6°, may be approximately or substantially 7°, may be approximately or substantially 8°, may be approximately or substantially 9°, may be approximately or substantially 10°, may be approximately or substantially 11°, or may be approximately or substantially 12°.

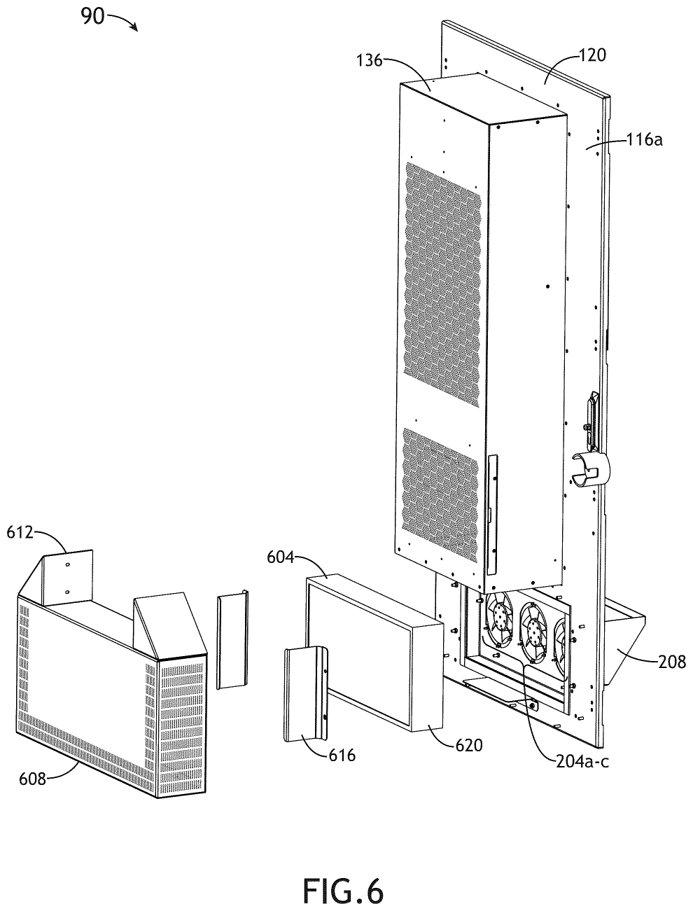

Details of the intake components 128 of the ECS 100 are illustrated in FIG. 6. The intake components 128 include a filter 604 (e.g., a hydrophobic box filter) that is positioned adjacent to the one or more fans 204a-c (e.g., the one or more fans moving or drawing air through the filter 604). The intake components may include a shroud 608 that is positioned over the filter 604 and configured to protect the filter 604, and one or more elements that secure the filter 604 and shroud 608 to the intake side 120 including but not limited to a filter shroud clamp 612 (e.g., configured to clamp the shroud to the primary cooling system 136), filter clamp brackets 616, and filter support brackets 620.

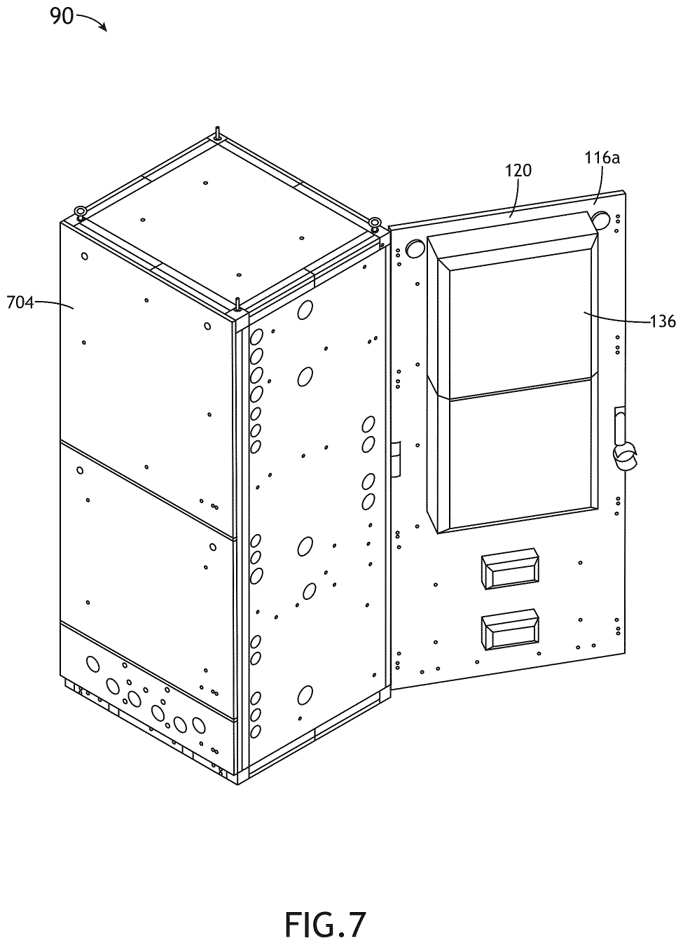

In embodiments, an outmoded cabinet 700 can be retrofitted with one or more elements of the ECS 100 (e.g., the ECS 100 configured as a retrofit kit), such as an outmoded cabinet 700 that includes a primary cooling system 136 but does not include an ECS 100 or an exhaust assembly 304, as illustrated in FIG. 7. For example, an upper rear panel 704 can be removed and replaced with the exhaust assembly 500 of FIG. 5A. In another example, one or more intake components 128 of the ECS 100 can be integrated into the intake side 120 of the outmode cabinet 700 (e.g., below the primary cooling system 136).

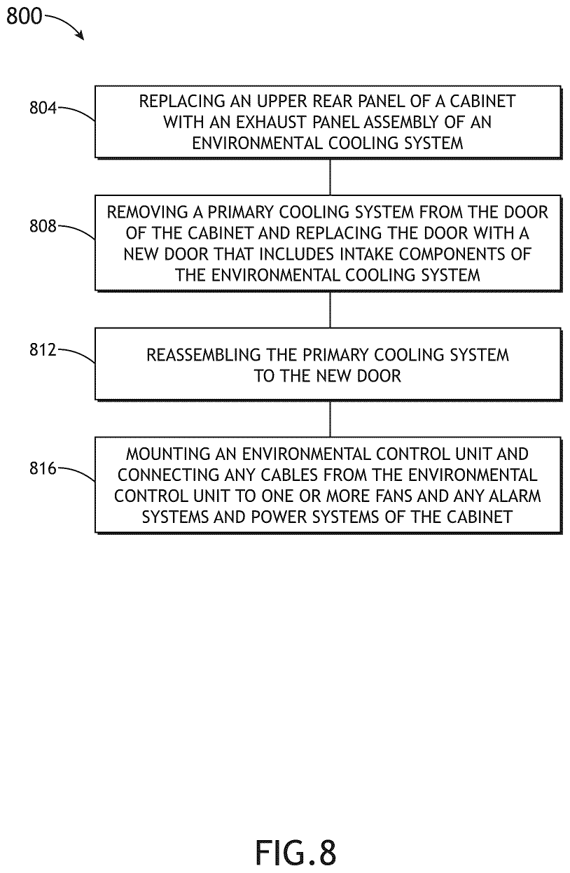

In embodiments, a method 800 of retrofitting the ECS 100 onto the outmoded cabinet 700 is disclosed, as illustrated in FIG. 8. In embodiments, the method includes a step 804 of replacing the upper rear panel 704 of the cabinet 90 with the exhaust panel assembly 500 of the ECS 100. The exhaust panel assembly 500 includes the exhaust panel 504 and the exhaust assembly 304. The exhaust panel assembly 500 may be preassembled.

In embodiments, the method 800 includes a step 808 of removing the primary cooling system 136 from the door 116a and replacing the door 116a with a new door that includes the intake components 128 of the ECS 100. The intake components may be preassembled to the door 116a. In embodiments, the method includes a step 812 of reassembling the primary cooling system 136 upon the new door.

In embodiments, the method includes a step 816 of mounting the environmental control unit 212 and connecting any cables from the environmental control unit 212 to the one or more fans 204a-c and any alarm systems and power systems of the cabinet 90. Because the cabinet 90 utilizes the exhaust assembly, there are no electrical or mechanical connections that need to be made between the exhaust assembly 304 and the environmental control unit 212, greatly simplifying the retrofit process.

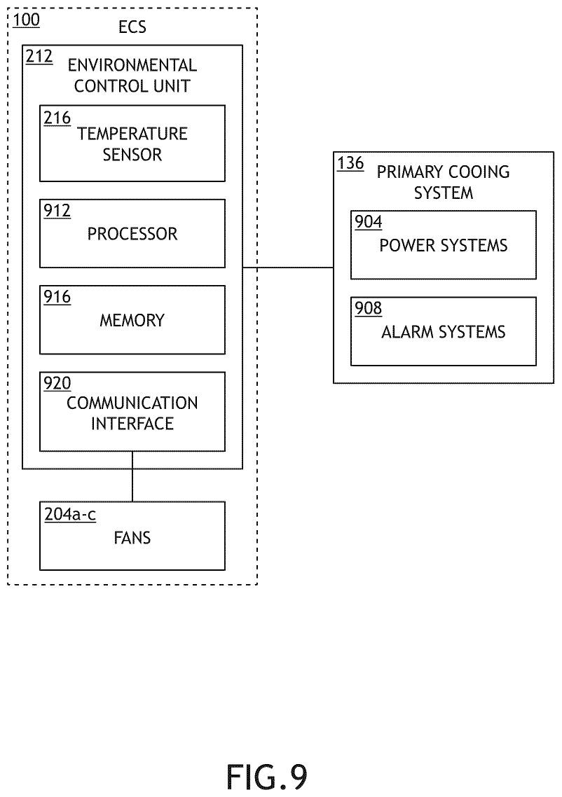

A schematic of power and data connectivity of the ECS 100 and the primary cooling system 136 is shown in FIG. 9. The environmental control unit 212 may be communicatively coupled at any time to one or more of the temperature sensor 216 (e.g., thermometer) and the one or more fans 204a-c as well as the primary cooling system 136, and may be coupled to the power systems 904 and alarm systems 908 of the primary cooling system. The environmental control unit 212 and/or ECS 100 may also include one or more processors 912, memory 916, and a communication interface. The one or more processors 912 are communicatively coupled to the electrical and sensor components of the ECS 100 (e.g., the one or more fans 204a-c, temperature sensor 216) and the primary cooling system 136. We note that there is no electrical (e.g., wireline) or wireless communication between the ECS 100 and the exhaust assembly 304.

In embodiments, the ECS 100 is configured to operate (e.g., activate or “turn on” the one or more fans 204a-c) if the primary cooling system 136 fails or becomes non-operational. Once the primary cooling system 136 fails or becomes non-operational, the ECS 100 provides the necessary cooling until the primary cooling system 136 can be repaired or replaced. The ECS 100 can operate independently of the primary cooling system 136. The ECS 100 may detect primary cooling system 136 failure in at least one of two or more methods. For example, the ECS 100 may detect damage or failure of the primary cooling system 136 via communication with the primary cooling system 136. For instance, the ECS 100 may receive an alarm signal, a loss of power signal, or an interruption of a signal from the primary cooling system 136, indicating a failure of the primary cooling system 136. In another example, the ECS 100 may detect a higher-than-normal temperature from the temperature sensor 216 (e.g., the temperature sensor may be monitoring a cold air return of the primary cooling system 136. Once the failure is detected, the ECS 100 will initiate the one or more fans 204a-c, which will cause air movement or an increase in air pressure that causes one or more flaps of the exhaust assembly 304 to move from the closed position to the open position, allowing air to escape the cabinet 90.

In embodiments, the ECS 100, the cabinet 90, or the primary cooling system 136 includes a dry contact “HVAC FAIL” alarm that activates for any event that disables the primary cooling system 136 or a cooling system outside of the cabinet 90). The alarm may be “normally closed”, but will open if the primary cooling system 136 or outside system loses power. The ECS 100 may also include a dip switch setting (e.g., on the environmental control unit 212).

In embodiments, the ECS 100 may be configured to activate when the temperature sensor 216 (e.g., communicating locally or remotely (wirelessly) with the environmental control unit 212) when the temperature sensor 216 reaches a threshold temperature, such as 45 degrees C. Once activated, the one or more fans 204a-c may operate at full speed for an entire period of operation of the ECS 100. The environmental control unit 212 may also be configured to deactivate power to the primary cooling system 136 (e.g., via a power relay). For example, a high-temperature reading by the temperature sensor 216 may indicate that the primary cooling system 136 is malfunctioning, prompting the ECS 100 to deactivate power to the primary cooling system 136 and activate the one or more fans 204a-c. The ECS 100 may be configured to turn off once the temperature sensor gives a reading below a predetermined threshold (e.g., below 25 degrees C.). The ECS 100 may then reactivate if the higher temperature or primary cooling system failure reoccurs.

In embodiments, the ECS 100 may be configured to generate an alarm upon a failure of one or more components of the ECS 100 or the primary cooling system 136. For example, the ECS 100 may be configured to generate an ECS failure alarm if one or more of the fans 204a-c, temperature sensor 216, or environmental control unit 212 are determined to be faulty. In another example, the ECS 100 may be configured to generate a primary cooling system failure alarm. In another example, the ECS 100 may be configured to generate an ECS 100 ON/OFF alarm, indicating the status of the operation (e.g., active or inactive) of the ECS 100. In another example, the environmental control unit is configured to operate the one or more fans 204a-c if the alarm system is activated.

The at least one processor 912 may be implemented as any suitable processor(s), such as at least one general purpose processor, at least one central processing unit (CPU), at least one image processor, at least one graphics processing unit (GPU), at least one field-programmable gate array (FPGA), and/or at least one special purpose processor configured to execute instructions for performing (e.g., collectively performing if more than one processor) any or all of the operations disclosed throughout.

The communication interface 920 can be operatively configured to communicate with one or more processors 912 and other components of the ECS 100. For example, the communication interface 920 can be configured to retrieve data from the temperature sensor 216 or other components of the ECS 100 or primary cooling system 136, transmit data for storage in the memory 916, retrieve data from storage in the memory 916, and so forth. The communication interface 920 can also be communicatively coupled with the one or more processors 912 and/or ECS and primary cooling system elements to facilitate data transfer between the ECS and primary cooling system elements.

Those having skill in the art will recognize that the state of the art has progressed to the point where there is little distinction left between hardware and software implementations of aspects of systems; the use of hardware or software is generally (but not always, in that in certain contexts the choice between hardware and software can become significant) a design choice representing cost vs. efficiency tradeoffs. Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be implemented, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations will typically employ optically oriented hardware, software, and/or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood by those within the art that each function and/or operation within such block diagrams, flowcharts, or examples can be implemented, individually and/or collectively, by a wide range of hardware, software, firmware, or virtually any combination thereof. In one embodiment, several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Video Disk (DVD), a digital tape, a computer memory, etc.; and a transmission type medium such as a digital and/or an analog communication medium (e.g., a fiber optic cable, a waveguide, a wired communications link, a wireless communication link, etc.).

In a general sense, those skilled in the art will recognize that the various aspects described herein, which can be implemented, individually and/or collectively, by a wide range of hardware, software, firmware, or any combination thereof, can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application-specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

Those having skill in the art will recognize that it is common within the art to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical data processing system may be implemented utilizing any suitable commercially available components, such as those typically found in data computing/communication and/or network computing/communication systems.

As used throughout and as would be appreciated by those skilled in the art, “at least one non-transitory computer-readable medium” or “memory” may refer to as at least one non-transitory computer-readable medium (e.g., e.g., at least one computer-readable medium implemented as hardware; e.g., at least one non-transitory processor-readable medium, at least one memory (e.g., at least one nonvolatile memory, at least one volatile memory, or a combination thereof; e.g., at least one random-access memory, at least one flash memory, at least one read-only memory (ROM) (e.g., at least one electrically erasable programmable read-only memory (EEPROM)), at least one on-processor memory (e.g., at least one on-processor cache, at least one on-processor buffer, at least one on-processor flash memory, at least one on-processor EEPROM, or a combination thereof), or a combination thereof), at least one storage device (e.g., at least one hard-disk drive, at least one tape drive, at least one solid-state drive, at least one flash drive, at least one readable and/or writable disk of at least one optical drive configured to read from and/or write to the at least one readable and/or writable disk, or a combination thereof), or a combination thereof).

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

### Emergency Cooling System

What is claimed:

1. An emergency cooling system for a cabinet comprising:
an exhaust assembly comprising:
an exhaust assembly frame comprising one or more exhaust apertures; and
one or more flaps configured to reversibly engage the one or more exhaust apertures.

2. The system of claim 1, wherein the one or more flaps are coupled via a hinge to the frame.

3. The emergency cooling system of claim 1, wherein a weight of the one or more flaps biases the one or more flaps toward a closed position.

4. The emergency cooling system of claim 1, further comprising:
an environmental control unit, the environmental control unit comprising:
one or more fans;
a temperature sensor;
at least one processor communicatively coupled to the one or more fans, the temperature sensor, and a primary cooling system, wherein the at least one processor is configured to:
determine an operating status of the primary cooling system;
receive temperature sensor data; and
activate the one or more fans based on at least one of the operating status of the primary cooling system of the temperature sensor data, wherein turning on the one or more fans causes an airflow or an increased air pressure within the cabinet that biases the one or more flaps into an open position.

5. The emergency cooling system of claim 4, wherein the at least one processor is configured to activate the one or more fans if the operating status of a primary cooling system comprises a failure.

6. The emergency cooling system of claim 4, wherein the at least one processor is configured to activate the one or more fans if the temperature sensor data comprises a temperature reading above a predetermined threshold.

7. The emergency cooling system of claim 1, wherein the one or more exhaust apertures or the one or more flaps are positioned at an angle relative to normal in a range of 2° to 15° when the one or more flaps are arranged in a closed position.

8. The emergency cooling system of claim 1, wherein the one or more exhaust apertures or the one or more flaps are positioned at an angle relative to normal of approximately 10° when the one or more flaps are arranged in a closed position.

9. The emergency cooling system of claim 4, further comprising a filter configured to filter air moved by the one or more fans.

10. The emergency cooling system of claim 9, wherein the filter is hydrophobic.

11. The emergency cooling system of claim 9, further comprising a shroud positioned over the filter and configured to protect the filter.

12. The emergency cooling system of claim 11, further comprising a filter shroud clamp configured to clamp the shroud to a primary emergency cooling system.

13. The emergency cooling system of claim 4, wherein the environmental control unit further includes or is coupled to an alarm system, wherein the environmental control unit is configured to operate the one or more fans if the alarm system is activated.

14. An emergency cooling system for a cabinet comprising:
an environmental control unit, the environmental control unit comprising:
one or more cooling fans;
a temperature sensor;
at least one processor communicatively coupled to the one or more cooling fans, the temperature sensor, and a primary cooling system, wherein the at least one processor is configured to:
determine an operating status of the primary cooling system;
receive temperature sensor data; and
activate the one or more fans based on at least one of the operating status of the primary cooling system of the temperature sensor data; and
an exhaust assembly comprising:
an exhaust assembly frame comprising one or more exhaust apertures; and
one or more flaps configured to reversibly engage the one or more exhaust apertures.

15. The emergency cooling system of claim 14, wherein the at least one processor is configured to activate the one or more fans if the operating status of primary cooling system comprises a failure.

16. The emergency cooling system of claim 14, wherein the at least one processor is configured to activate the one or more fans if the temperature sensor data comprises a temperature reading above a predetermined threshold.

17. The emergency cooling system of claim 14, wherein a weight of the one or more flaps biases the one or more flaps toward a closed position.

18. The emergency cooling system of claim 14, wherein the emergency cooling system is configured as a retrofit kit.

19. The emergency cooling system of claim 14, wherein the one or more exhaust apertures or the one or more flaps are positioned at an angle relative to normal in a range of 2° to 15° when the one or more flaps are arranged in a closed position.

20. A method for retrofitting a cabinet with an emergency cooling system, comprising:
replacing a panel of a cabinet with an exhaust panel assembly of an emergency cooling system;
removing a primary cooling system from a door of the cabinet and replacing the door with a new door that includes an intake component of the emergency cooling system;
reassembling the primary cooling system to the new door; and
mounting an environmental control unit and connecting one or more cables from the environmental control unit to one or more fans, alarm systems, or power systems of the cabinet.
